(19) United States
(12) Patent Application Publication
(10) Pub. No.: US 2024/0016022 A1
(43) Pub. Date: Jan. 11, 2024

(54) DISPLAY PANEL AND DISPLAY DEVICE

(71) Applicants: WUHAN CHINA STAR OPTOELECTRONICS TECHNOLOGY CO., LTD., Wuhan Hubei (CN); WUHAN CHINA STAR OPTOELECTRONICS SEMICONDUCTOR DISPLAY TECHNOLOGY CO., LTD., Wuhan, Hubei (CN)

(72) Inventor: Yu YAN, Wuhan Hubei (CN)

(21) Appl. No.: 17/297,905

(22) PCT Filed: May 6, 2021
(86) PCT No.: PCT/CN2021/091888

§ 371 Date: Oct. 27, 2022

(30) Foreign Application Priority Data
Apr. 22, 2021 (CN) 202110435782.1

(51) Int. Cl. H10K 59/38; H10K 59/126; H10K 59/80

(52) U.S. Cl. CPC H10K 59/38; H10K 59/126; H10K 59/873; H10K 2102/351

(57) ABSTRACT

A display panel and a display device are provided. The display panel includes an array substrate, a light-emitting device layer, and an ultraviolet light conversion layer. The ultraviolet light conversion layer is configured to convert high-energy ultraviolet light into low-energy ultraviolet light. When external high-energy ultraviolet light passes through the ultraviolet light conversion layer, it is converted into low-energy ultraviolet light by the ultraviolet light conversion layer. Low-energy ultraviolet light reaching inside of the panel has less influence on a luminescent material of the panel, thereby improving performance and service life of the display panel.

### FIELD OF INVENTION

The present application relates to a field of manufacturing of display panels, and in particular to a display panel and a display device.

### BACKGROUND OF INVENTION

With continuous progress of display technology, people have higher requirements on the performance and quality of display panels and display devices.

Compared with traditional liquid crystal displays (LCDs), organic light-emitting diode (OLED) devices have advantages of light weight, wide viewing angles, fast response times, low-temperature resistance, and high luminous efficiency. Therefore, they have been regarded as a next-generation display technology in display industry, especially OLED can be applied to various types of equipment. However, during use of current display devices and equipment, due to their complicated operating conditions, storage environments of the equipment are relatively harsh. For example, some equipment often works under solar radiation or high temperature environments. In this situation, harsh environments will have a certain impact on performance and service life of the device, especially impact of high-intensity ultraviolet rays from outside on the equipment. An external high-intensity ultraviolet light radiation will cause certain damage to film materials inside an OLED device, thereby affecting service life of the OLED device, and is not conducive to improvement of equipment performance.

Therefore, it is necessary to propose solutions to these problems in prior art.

### Technical Problem

As mentioned above, when an OLED device manufactured in current manufacturing technology operates under complex environmental conditions, radiation of high-energy ultraviolet light will cause a certain degree of damage to functional film layers inside the device. Therefore, service life and reliability of display devices are reduced, which is not conducive to improving performance of equipment.

### SUMMARY OF INVENTION

In order to solve the above-mentioned problems, embodiments of the present application provide a display panel and a display device to effectively improve the problem that under complex operating conditions of current display panels and devices, high-energy ultraviolet rays from outside are likely to damage internal film layers of the device, which affects the normal performance of the device.

In order to solve above technical problems, technical solutions provided by embodiments of the present application are as follows:

In a first aspect of the embodiments of the present application, a display panel is provided, including: an array substrate; a light-emitting device layer disposed on the array substrate; and an ultraviolet light conversion layer disposed on a light-emitting side of the light-emitting device layer and configured to convert high-energy ultraviolet light into low-energy ultraviolet light, wherein the ultraviolet light conversion layer includes light-absorbing ions and concentrations of the light-absorbing ions distributed in different regions of the ultraviolet light conversion layer are different.

According to an embodiment of the present application, the light-absorbing ions include at least one of Yb³⁺, Tm³⁺, or Ce³⁺.

According to an embodiment of the present application, the light-absorbing ions are uniformly arranged in the ultraviolet light conversion layer, and a content of the light-absorbing ions ranges from 1% to 10%.

According to an embodiment of the present application, a thickness of the ultraviolet light conversion layer ranges from 1 μm to 10 μm.

According to an embodiment of the present application, wavelengths of photons in the low-energy ultraviolet light range from 900 nm to 1100 nm.

According to an embodiment of the present application, the display panel further includes an encapsulation layer and a protective layer, the encapsulation layer is disposed on the light-emitting side of the light-emitting device layer, and the protective layer is disposed on the encapsulation layer.

According to an embodiment of the present application, the encapsulation layer is disposed on the light-emitting device layer, the ultraviolet light conversion layer is disposed on the encapsulation layer, and the protective layer is disposed on the ultraviolet light conversion layer.

According to an embodiment of the present application, the ultraviolet light conversion layer is disposed on the light-emitting device layer, the encapsulation layer is disposed on the ultraviolet light conversion layer, and the protective layer is disposed on the encapsulation layer.

In a second aspect of the embodiments of the present application, a display panel is provided, including: an array substrate; a light-emitting device layer disposed on the array substrate; and an ultraviolet light conversion layer disposed on a light-emitting side of the light-emitting device layer and configured to convert high-energy ultraviolet light into low-energy ultraviolet light.

According to an embodiment of the present application, the ultraviolet light conversion layer includes light-absorbing ions.

According to an embodiment of the present application, the light-absorbing ions include at least one of Yb³⁺, Tm³⁺, or Ce³⁺.

According to an embodiment of the present application, a content of the light-absorbing ions ranges from 1% to 10%.

According to an embodiment of the present application, a thickness of the ultraviolet light conversion layer ranges from 1 μm to 10 μm.

According to an embodiment of the present application, wavelengths of photons in the low-energy ultraviolet light range from 900 nm to 1100 nm.

According to an embodiment of the present application, the display panel further includes an encapsulation layer and a protective layer, the encapsulation layer is disposed on the light-emitting side of the light-emitting device layer, and the protective layer is disposed on the encapsulation layer.

According to an embodiment of the present application, the encapsulation layer is disposed on the light-emitting device layer, the ultraviolet light conversion layer is disposed on the encapsulation layer, and the protective layer is disposed on the ultraviolet light conversion layer.

According to an embodiment of the present application, the ultraviolet light conversion layer is disposed on the light-emitting device layer, the encapsulation layer is disposed on the ultraviolet light conversion layer, and the protective layer is disposed on the encapsulation layer.

According to a third aspect of the embodiments of the present application, a display device is further provided. The display device includes the display panel provided in the embodiment of the present application, and the display panel includes: an array substrate; a light-emitting device layer disposed on the array substrate; and an ultraviolet light conversion layer disposed on a light-emitting side of the light-emitting device layer and configured to convert high-energy ultraviolet light into low-energy ultraviolet light.

According to an embodiment of the present application, a thickness of the ultraviolet light conversion layer ranges from 1 μm to 10 μm.

According to an embodiment of the present application, the ultraviolet light conversion layer includes light-absorbing ions.

As mentioned above, beneficial effects of the embodiments of the present application are as follows: This embodiment of the present application provides a display panel and a display device to effectively enable the display panel to have greater performance during use and reduce the impact of external high-energy ultraviolet light on the equipment. In the embodiment of the present application, an ultraviolet light conversion layer is disposed inside the display panel, and the ultraviolet light conversion layer is disposed on a light-emitting side of a light-emitting device layer of the display panel. When an external high-energy ultraviolet light passes through the ultraviolet light conversion layer, it is converted into low-energy ultraviolet light by the ultraviolet light conversion layer. The low-energy ultraviolet light reaching inside of the panel has less and even no effect on the luminescent material of the panel, thereby effectively improving the performance and increasing service life of the display panel.

### DESCRIPTION OF DRAWINGS

FIG. 1 is a schematic structural diagram of a film layer of a display panel provided by an embodiment of the application.

FIG. 2 is a schematic structural diagram of a film layer of another display panel provided by an embodiment of the application.

FIG. 3 is a schematic structural diagram of another film layer provided by an embodiment of the application.

FIG. 4 is a schematic structural diagram of functional film layers provided by an embodiment of the application.

FIG. 5 is a schematic structural diagram of a film layer of a polarizer provided by an embodiment of the application.

### DETAILED DESCRIPTION OF PREFERRED EMBODIMENTS

The description of the embodiments refers to the attached drawings to illustrate specific embodiments in which the present disclosure can be implemented.

With the continuous progress of display technology, people hope to manufacture and obtain display panels and display devices with better luminous performance and display effects. In addition, it is also necessary to obtain a display device that can work normally under various complex environmental conditions and still has good performance and service life under high-intensity ultraviolet light.

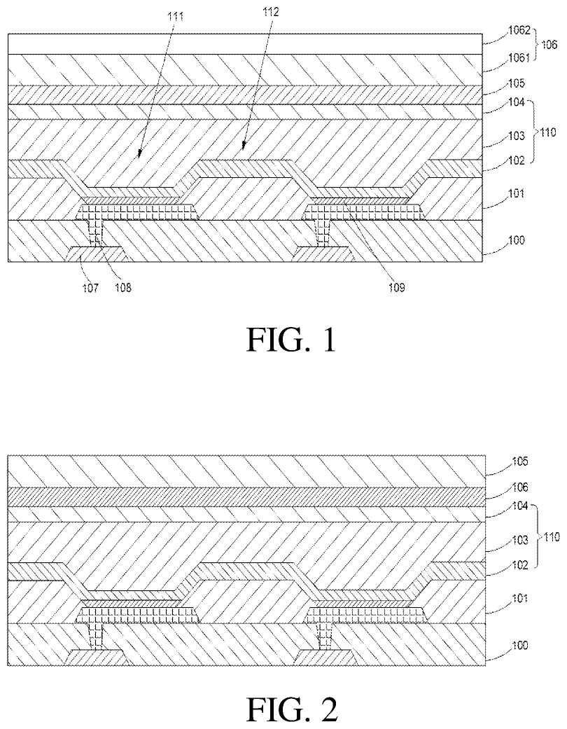

As shown in FIG. 1, FIG. 1 is a schematic structural diagram of a film layer of a display panel provided by an embodiment of the application. The display panel includes an array substrate 100, a pixel definition layer 101, an encapsulation layer 110, a display layer 105, and an ultraviolet light conversion layer 106.

Specifically, the array substrate 100 in the embodiment of the present application is disposed on a substrate layer. The array substrate 100 may be a thin-film transistor array substrate, and a plurality of thin-film transistor devices are disposed on the array substrate 100.

The pixel definition layer 101 is disposed on the array substrate 100, and the pixel definition layer 101 is patterned on the array substrate 100. Therefore, a pixel opening area 111 and a pixel non-aperture area 112 are formed on the array substrate 100, wherein the pixel opening area 111 and the pixel non-aperture area 112 are arranged adjacent to each other.

In the embodiment of the present application, the display panel further includes an electrode layer 108 and a light-emitting device layer 109. The electrode layer 108 is electrically connected to a source 107 of the thin-film transistor on the array substrate 100 through a corresponding via hole. When the electrode layer 108 is disposed, the electrode layer 108 is correspondingly arranged at a position of the pixel opening area 111 of the pixel definition layer 101. In addition, the light-emitting device layer 109 is disposed on the electrode layer 108, and the light-emitting device layer 109 is disposed at a position corresponding to the pixel opening area 111 of the pixel definition layer 101.

Therefore, the thin-film transistors on the array substrate 100 can drive and control the light-emitting device layer 109 through the electrode layer 108. In addition, the light emitted from the light-emitting device layer 109 passes through the pixel opening area 111 to reach the outside of the display panel and finally realizes a light-emitting display function.

Further, the encapsulation layer 110 is disposed on the pixel definition layer 101. The encapsulation layer 110 realizes sealing of film layers in the display panel and prevents external water vapor and other substances from entering the light-emitting device layer 109 of the display panel to affect performance of the display panel.

The encapsulation layer 110 in the embodiment of the present application may include a superimposed structure of multiple film layers. Specifically, the encapsulation layer 110 may include a first inorganic layer 102, a first organic layer 103, and a second inorganic layer 104. Wherein, the first inorganic layer 102 is disposed on the pixel definition layer 101, and the first inorganic layer 102 covers the pixel definition layer 101 and the light-emitting device layer 109. The first organic layer 103 is disposed on the first inorganic layer 102, and the second inorganic layer 104 is disposed on the first organic layer 103. Due to a laminated structure in which the inorganic layer and the organic layer are sequentially superimposed, when impurities, such as external water vapor, enter the encapsulation layer 110, the multi-layer structure can effectively block the impurities, thereby effectively improving packaging performance and packaging effect of the encapsulation layer 110. Preferably, the material of the first inorganic layer 102 and the second inorganic layer 104 may be an insulating material such as silicon nitride or silicon oxide.

In an embodiment of the present application, the display layer 105 is disposed on the encapsulation layer 110, and the luminous display is performed on the display screen through the display layer 105. Preferably, the display layer 105 may be a quantum dot light-emitting device layer, thereby effectively improving the light-emitting display effect of the display panel.

Wherein, the display panel further includes the ultraviolet light conversion layer 106. As shown in FIG. 1, in the embodiment of the present application, the ultraviolet light conversion layer 106 is disposed on the display layer 105. When the external ultraviolet light reaches the ultraviolet light conversion layer 106, in the process of passing through the ultraviolet light conversion layer 106, the ultraviolet light conversion layer 106 can convert the ultraviolet light with higher energy into ultraviolet light with low energy.

Specifically, if the external light is sunlight, the photon wavelength of ultraviolet light in the sunlight spectrum ranges from 300 nm to 400 nm. These ultraviolet photons have a high luminous intensity, and can easily damage the light-emitting device layer 109 inside the display panel and affect the service life of the panel. In the embodiment of the present application, when these high-intensity photons pass through the ultraviolet light conversion layer 106, the ultraviolet light conversion layer 106 can convert the high-energy photons into low-energy ultraviolet light. For example, the photons with the above-mentioned wavelengths are converted into ultraviolet light with a wavelength ranges from 900 nm to 1100 nm, thereby effectively reducing the intensity of the ultraviolet light, protecting the sensitive film layers inside the display panel, and increasing the service life of the display panel.

Preferably, the ultraviolet light conversion layer 106 provided in the embodiment of the present application includes light-absorbing ions. The light-absorbing ions may include Yb³⁺, Tm³⁺, and Ce³⁺, etc., wherein the light-absorbing ions in the ultraviolet light conversion layer 106 may include at least one of the aforementioned ions.

When the ultraviolet light passes through the light-absorbing ions, the light-absorbing ions can perform quantum-cutting on the ultraviolet light. Specifically, the light-absorbing ions absorb one high-energy photon, converts the absorbed high-energy photon into two low-energy photons, and emits the low-energy photons, thereby effectively reducing the intensity of ultraviolet light.

When disposing the ultraviolet light conversion layer 106, the light-absorbing ions can be uniformly distributed in the ultraviolet light conversion layer 106, and a content of the light-absorbing ions ranges from 1% to 10%. Preferably, the content of the light-absorbing ions is 5%. Specifically, for actual products, the content of light-absorbing ions can be adjusted according to requirements.

Further, when disposing light-absorbing ions, different concentrations of light-absorbing ions can be arranged at different positions (regions) of the ultraviolet light conversion layer 106. For example, at a position corresponding to the pixel opening area 111 of the pixel definition layer 101, the concentration of the light-absorbing ions is greater than the concentration of other light-absorbing ions at a position corresponding to the pixel non-aperture area 112. In this way, when external light enters the pixel opening area 111, the high-energy ultraviolet light of the light can be effectively converted, thereby reducing the damage of the ultraviolet light to the light-emitting device layer and improving performance of the panel.

The thickness of the ultraviolet light conversion layer 106 in the embodiment of the present application ranges from 1 μm to 10 μm, preferably 5 μm. In addition, it can be adjusted according to the needs of the actual product, so as to achieve a thin and light design while ensuring the conversion of ultraviolet light.

In addition, in order to ensure the transmittance of light, the ultraviolet light conversion layer 106 in the embodiment of the present application is a transparent film layer. Preferably, the transparent film layer may be a transparent base layer containing Yb³⁺. Specifically, the transparent base layer may be a transparent base layer containing CsPbX₃, wherein X in the chemical formula can be chlorine, bromine, iodine, etc., or other halogen elements in the periodic table, or the transparent base layer can be oxide or fluoride. Preferably, the oxide or fluoride is G₂O₃, Y₂O₃, CeO₂, NaYF₄, LaF₃, or K₂GdF₅, etc., which will not be described in detail herein.

Preferably, the ultraviolet light conversion layer can be provided in a multilayer structure. For example, a first ultraviolet light conversion layer 1061 and a second ultraviolet light conversion layer 1062, wherein the content of light-absorbing ions in the first ultraviolet light conversion layer 1061 is less than the content of light-absorbing ions in the second ultraviolet light conversion layer 1062, thereby forming an ultraviolet light conversion layer with a concentration gradient. When the ultraviolet light reaches the film layer, light-absorbing ions of different concentrations can better convert the ultraviolet light, thereby effectively improving the conversion rate of external light, and further improving protection of the light-emitting device layer in the panel.

Further, the ultraviolet light conversion layer 106 in the embodiment of the present application may also be provided as one layer. However, for the one film layer, in order to increase the light conversion rate of the ultraviolet light conversion layer 106, the concentration of light-absorbing ions in the film layer or the content of light-absorbing ions distributed in a unit area gradually increases from top to bottom. Thus, the efficiency of converting ultraviolet light by the ultraviolet light conversion layer 106 is effectively improved.

As shown in FIG. 2, FIG. 2 is a schematic structural diagram of a film layer of another display panel provided by an embodiment of the application. Please also refer to the film layer structure of the display panel in FIG. 1. In the embodiment of the present application, the ultraviolet light conversion layer 106 is disposed on the encapsulation layer 110, and the display layer 105 is disposed on the ultraviolet light conversion layer 106. That is, the ultraviolet light conversion layer 106 is disposed between the film layers of the display panel to further improve the conversion performance of ultraviolet light.

Preferably, the ultraviolet light conversion layer 106 can be formed by an evaporation process or a chemical vapor deposition process to ensure the uniformity of the ultraviolet light conversion layer 106 and particle distribution uniformity.

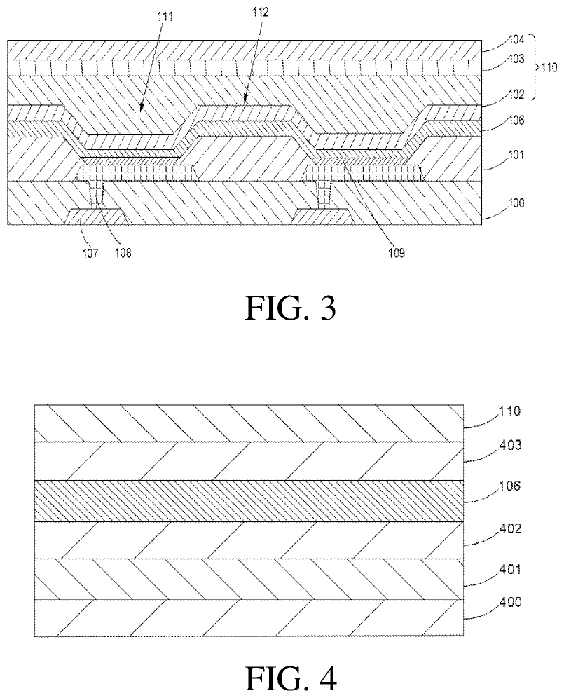

As shown in FIG. 3, FIG. 3 is a schematic structural diagram of another film layer provided by an embodiment of the application. Please refer to the structures in FIG. 1 and FIG. 2 together. In this embodiment, the panel includes an array substrate 100, a pixel definition layer 101, an encapsulation layer 110, and an ultraviolet light conversion layer 106.

Specifically, the pixel definition layer 101 is disposed on the array substrate 100, and the pixel definition layer 101 is patterned on the array substrate 100 to form a pixel opening area 111 and a pixel non-aperture area 112, and the pixel opening area 111 and the pixel non-aperture area 112 are arranged adjacent to each other.

The display panel further includes an electrode layer 108 and a light-emitting device layer 109. The electrode layer 108 is electrically connected to a source 107 of the thin-film transistor on the array substrate 100 through a corresponding via hole. In addition, the electrode layer 108 and the light-emitting device layer 109 are correspondingly arranged at the pixel opening area 111 of the pixel definition layer 101.

The encapsulation layer 110 is disposed on the pixel definition layer 101, and the encapsulation layer 110 realizes the sealing of the film layers in the display panel. The encapsulation layer 110 in the embodiment of the present application may include a stacked structure of multiple film layers. The specific structure will not be described in detail herein.

Preferably, the display panel further includes an ultraviolet light conversion layer 106. In the embodiment of the present application, the ultraviolet light conversion layer 106 is disposed on the pixel definition layer 101. In addition, the ultraviolet light conversion layer 106 covers the light-emitting device layer 109 and the pixel definition layer 101.

When external ultraviolet light enters the display panel and passes through the ultraviolet light conversion layer 106, the ultraviolet light conversion layer 106 can convert high-energy ultraviolet light into low-energy ultraviolet light, thereby effectively protecting the light-emitting device layer 109. Preferably, when the ultraviolet light conversion layer 106 is provided, in order to further improve the light conversion performance, the thickness of the ultraviolet light conversion layer 106 at a position corresponding to the pixel opening area 111 may be greater than the thickness of the ultraviolet light conversion layer 106 at a position corresponding to the pixel non-aperture area 112. Alternatively, the concentration of light-absorbing ions in the film layer corresponding to the pixel opening area 111 is increased to effectively convert the high-energy ultraviolet light.

As shown in FIG. 4, FIG. 4 is a schematic structural diagram of the functional film layers provided by an embodiment of the application. These film layers are the main film layers when the display panel is working normally. The structure of each film layer is only an example. In addition, the display panel also includes other functional film layers. In this schematic diagram, other functional film layers are omitted.

Specifically, the functional layers include a light-emitting device layer 400, an electrode layer 401, a covering layer 402, an ultraviolet light conversion layer 106, a light coupling layer 403, and an encapsulation layer 110. Wherein, the electrode layer 401 is disposed on the light-emitting device layer 400, the covering layer 402 is disposed on the electrode layer 401, and the ultraviolet light conversion layer 106 is disposed on the covering layer 402. In addition, the light coupling layer 403 is disposed on the ultraviolet light conversion layer 106, and the encapsulation layer 110 is disposed on the light coupling layer 403.

In the embodiment of the present application, the ultraviolet light conversion layer 106 is disposed between the light coupling layer 403 and the covering layer 402. When the external ultraviolet light passes through the above-mentioned film layers in sequence and enters the display panel, the ultraviolet light conversion layer 106 can effectively convert a high-energy ultraviolet light into a low-energy ultraviolet light, thereby playing a role in preventing ultraviolet rays, protecting the light-emitting device layer 400, and improving reliability of the display panel.

Specifically, the light coupling layer 403 may be a lithium fluoride (LiF) film layer. The LiF film layer can effectively increase the light output rate and improve display effect of the display panel.

Further, the ultraviolet light conversion layer 106 can also be disposed between the electrode layer 401 and the covering layer 402, and the specific structure is not described in detail. By changing the position of the ultraviolet light conversion layer 106, the conversion performance of the ultraviolet light conversion layer 106 for ultraviolet light can be further improved.

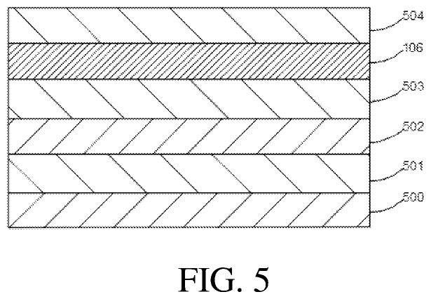

The embodiment of the application further provides a polarizer. As shown in FIG. 5, FIG. 5 is a schematic structural diagram of a film layer of a polarizer provided by an embodiment of the application. The polarizer includes multiple polarizing film layers and specifically includes a substrate 500, an adhesive layer 501, a first supporting layer 502, a first polarizing layer 503, an ultraviolet light conversion layer 106, and a second supporting layer 504.

Specifically, the first supporting layer 502 and the second supporting layer 504 in the embodiment of the present application may be the same material, that is, they may be the same layer, preferably a triacetate cellulose (TAC) supporting layer. The adhesive layer 501 may be a pressure-sensitive adhesive, so as to bond two adjacent film layers. The first polarizing layer 503 can be polyvinyl alcohol (PVA) polarizing layer, and the light is deflected by the PVA polarizing layer. Preferably, the polarizer provided in the embodiment of the present application may be provided with multiple first polarizing layers 503 to effectively improve polarization performance of the polarizer.

The polarizer in the embodiment of the present application is provided with an ultraviolet light conversion layer 106, and the ultraviolet light conversion layer 106 is preferably a Yb³⁺ base layer. The ultraviolet light conversion layer 106 is disposed between the supporting layer and the polarizing layer of the polarizer, so as to effectively convert high-energy ultraviolet light and improve the performance of the polarizer.

Further, an embodiment of the present application further provides a display device, and the display panel in the embodiment of the present application or the polarizer in the embodiment of the present application is disposed in the display device. An ultraviolet light conversion layer is provided in the film layers. When high-energy ultraviolet light passes through the ultraviolet light conversion layer, the ultraviolet light conversion layer converts the ultraviolet light into low-energy ultraviolet light, thereby effectively preventing damage to the film layers in the organic light-emitting diodes (OLED) and improving the anti-ultraviolet performance of the display panel.

This article gives a detailed introduction to a display panel and a display device provided by the embodiments of the present application. In this article, specific embodiments are used to illustrate the principle and implementation of the application. The description of the embodiments is only to help understand the technical solutions and core ideas of the application. Those of ordinary skill in the art should understand that they can still modify the technical solutions in the embodiments, or equivalently replace some of the technical features. These modifications or replacements do not cause the essence of the corresponding technical solutions to deviate from the scope of the technical solutions in the embodiments of the present application.

What is claimed is:

1. A display panel, comprising:
an array substrate;
a light-emitting device layer disposed on the array substrate; and
an ultraviolet light conversion layer disposed on a light-emitting side of the light-emitting device layer and configured to convert high-energy ultraviolet light into low-energy ultraviolet light, wherein the ultraviolet light conversion layer comprises light-absorbing ions, and concentrations of the light-absorbing ions in different regions of the ultraviolet light conversion layer are different.

2. The display panel according to claim 1, wherein the light-absorbing ions comprise at least one of Yb³⁺, Tm³⁺, or Ce³⁺.

3. The display panel according to claim 1, wherein a content of the light-absorbing ions ranges from 1% to 10%.

4. The display panel according to claim 1, wherein a thickness of the ultraviolet light conversion layer ranges from 1 μm to 10 μm.

5. The display panel according to claim 1, wherein wavelengths of photons in the low-energy ultraviolet light range from 900 nm to 1100 nm.

6. The display panel according to claim 1, further comprising an encapsulation layer and a protective layer, wherein the encapsulation layer is disposed on the light-emitting side of the light-emitting device layer, and the protective layer is disposed on the encapsulation layer.

7. The display panel according to claim 6, wherein the encapsulation layer is disposed on the light-emitting device layer, the ultraviolet light conversion layer is disposed on the encapsulation layer, and the protective layer is disposed on the ultraviolet light conversion layer.

8. The display panel according to claim 6, wherein the ultraviolet light conversion layer is disposed on the light-emitting device layer, the encapsulation layer is disposed on the ultraviolet light conversion layer, and the protective layer is disposed on the encapsulation layer.

9. A display panel, comprising:
an array substrate;
a light-emitting device layer disposed on the array substrate; and
an ultraviolet light conversion layer disposed on a light-emitting side of the light-emitting device layer and configured to convert high-energy ultraviolet light into low-energy ultraviolet light.

10. The display panel according to claim 9, wherein the ultraviolet light conversion layer comprises light-absorbing ions.

11. The display panel according to claim 10, wherein the light-absorbing ions comprise at least one of Yb³⁺, Tm³⁺, or Ce³⁺.

12. The display panel according to claim 11, wherein a content of the light-absorbing ions ranges from 1% to 10%.

13. The display panel according to claim 9, wherein a thickness of the ultraviolet light conversion layer ranges from 1 μm to 10 μm.

14. The display panel according to claim 9, wherein wavelengths of photons in the low-energy ultraviolet light range from 900 nm to 1100 nm.

15. The display panel according to claim 9, further comprising an encapsulation layer and a protective layer, wherein the encapsulation layer is disposed on the light-emitting side of the light-emitting device layer, and the protective layer is disposed on the encapsulation layer.

16. The display panel according to claim 15, wherein the encapsulation layer is disposed on the light-emitting device layer, the ultraviolet light conversion layer is disposed on the encapsulation layer, and the protective layer is disposed on the ultraviolet light conversion layer.

17. The display panel according to claim 15, wherein the ultraviolet light conversion layer is disposed on the light-emitting device layer, the encapsulation layer is disposed on the ultraviolet light conversion layer, and the protective layer is disposed on the encapsulation layer.

18. A display device, comprising a display panel, wherein the display panel comprises:
an array substrate;
a light-emitting device layer disposed on the array substrate; and
an ultraviolet light conversion layer disposed on a light-emitting side of the light-emitting device layer and configured to convert high-energy ultraviolet light into low-energy ultraviolet light.

19. The display device according to claim 18, wherein a thickness of the ultraviolet light conversion layer ranges from 1 μm to 10 μm.

20. The display device according to claim 18, wherein the ultraviolet light conversion layer comprises light-absorbing ions.
